(19) United States
(12) Patent Application Publication
(10) Pub. No.: US 2018/0269384 A1
(43) Pub. Date: Sep. 20, 2018

(54) METHOD AND SYSTEM FOR PROVIDING A DUAL MAGNETIC JUNCTION HAVING MITIGATED FLOWERING FIELD EFFECTS

(71) Applicant: Samsung Electronics Co., LTD., Gyeonggi-do (KR)

(72) Inventors: Shuxia Wang, San Jose, CA (US); Dmytro Apalkov, San Jose, CA (US); Vladimir Nikitin, Campbell, CA (US)

(21) Appl. No.: 15/976,844

(22) Filed: May 10, 2018

Related U.S. Application Data
(62) Division of application No. 15/396,296, filed on Dec. 30, 2016.

(51) Int. Cl. H01L 43/02; H01L 43/12; H01L 43/10; H01L 43/08; H01L 27/22; G11C 11/16

(52) U.S. Cl. CPC H01L 43/02; H01L 43/12; H01L 43/10; G11C 11/161; H01L 27/226; G11C 11/165; H01L 43/08

(57) ABSTRACT

A magnetic junction and method for providing the magnetic junction are described. The magnetic junction includes a free layer, first and second reference layers, and first and second nonmagnetic spacer layers. The free layer is switchable between stable magnetic states. The first and second nonmagnetic spacer layers are between the free layer and first and second reference layers. The first and second reference layers have first and second reference layer magnetic lengths. The free layer has a free layer magnetic length less than the free layer physical length and less than the first and second reference layer magnetic lengths. The free layer magnetic length has a first end and a second end opposite to the first end. The free layer and the reference layers are oriented such that the first and second reference layer magnetic lengths extend past the first and second ends of the free layer.

### CROSS-REFERENCE TO RELATED APPLICATIONS

This application is a divisional of U.S. patent application Ser. No. 15/396,296, filed Dec. 30, 2016, entitled METHOD AND SYSTEM FOR PROVIDING A DUAL MAGNETIC JUNCTION HAVING MITIGATED FLOWERING FIELD EFFECTS, assigned to the assignee of the present application, and incorporated herein by reference.

### BACKGROUND OF THE INVENTION

Magnetic memories, particularly magnetic random access memories (MRAMs), have drawn increasing interest due to their potential for high read/write speed, excellent endurance, non-volatility and low power consumption during operation. An MRAM can store information utilizing magnetic materials as an information recording medium. One type of MRAM is a spin transfer torque random access memory (STT-MRAM). STT-MRAM utilizes magnetic junctions written at least in part by a current driven through the magnetic junction. A spin polarized current driven through the magnetic junction exerts a spin torque on the magnetic moments in the magnetic junction. As a result, layer(s) having magnetic moments that are responsive to the spin torque may be switched to a desired state.

For example, a conventional magnetic tunneling junction (MTJ) may be used in a conventional STT-MRAM. The conventional MTJ typically resides on a substrate. The conventional MTJ, uses conventional seed layer(s), may include capping layers and may include a conventional antiferromagnetic (AFM) layer. The conventional MTJ includes a conventional reference layer, a conventional free layer and a conventional tunneling barrier layer between the conventional pinned and free layers. A bottom contact below the conventional MTJ and a top contact on the conventional MTJ may be used to drive current through the conventional MTJ in a current-perpendicular-to-plane (CPP) direction.

The conventional reference layer and the conventional free layer are magnetic. The magnetization of the conventional reference layer is fixed, or pinned, in a particular direction. The conventional free layer has a changeable magnetization. The conventional free layer may be a single layer or include multiple layers.

To switch the magnetization of the conventional free layer, a current is driven perpendicular to plane. When a sufficient current is driven from the top contact to the bottom contact, the magnetization of the conventional free layer may switch to be parallel to the magnetization of a conventional bottom reference layer. When a sufficient current is driven from the bottom contact to the top contact, the magnetization of the free layer may switch to be antiparallel to that of the bottom reference layer. The differences in magnetic configurations correspond to different magnetoresistances and thus different logical states (e.g. a logical “0” and a logical “1”) of the conventional MTJ.

Because of their potential for use in a variety of applications, research in magnetic memories is ongoing. Mechanisms for improving the performance of STT-MRAM are desired. For example, a lower switching current may be desired for easier and faster switching. Concurrently, a magnetic junction having larger lateral (in-plane) dimensions may be desirable. However both these goals may be difficult to achieve together. Accordingly, what is needed is a method and system that may improve the performance of the spin transfer torque based memories. The method and system described herein address such a need.

### BRIEF SUMMARY OF THE INVENTION

A magnetic junction and method for providing the magnetic junction are described. The magnetic junction is usable in a magnetic device. The magnetic junction includes a free layer, first and second reference layers, and first and second nonmagnetic spacer layers. The free layer is switchable between stable magnetic states. The first nonmagnetic spacer layer is between the first reference layer and the free layer. The second nonmagnetic spacer layer is between the free layer and the second reference layer. The free layer is between the first nonmagnetic spacer layer and the second nonmagnetic spacer layer. The first reference layer has a first reference layer magnetic length. The second reference layer has a second reference layer magnetic length. The free layer has a free layer magnetic length less than the free layer physical length, less than the first reference layer magnetic length and less than the second reference layer magnetic length. The free layer magnetic length has a first end and a second end opposite to the first end. The free layer and the first reference layer are oriented such that the first reference layer magnetic length extends past the first end and past the second end of the free layer. The free layer and the second reference layer are oriented such that the second reference layer magnetic length extends past the first end and past the second end of the free layer.

The magnetic junction has a more uniform magnetic field at the free layer. As a result, switching performance may be improved.

### BRIEF DESCRIPTION OF SEVERAL VIEWS OF THE DRAWINGS

FIGS. 1A-1B depict an exemplary embodiment of a dual magnetic junction usable in a magnetic devices such as a magnetic memory programmable using spin transfer torque and having a reduced magnetic length free layer.

FIG. 2 depicts another exemplary embodiment of a dual magnetic junction usable in a magnetic devices and having a reduced magnetic length free layer.

FIG. 3 depicts another exemplary embodiment of a dual magnetic junction usable in a magnetic devices and having a reduced magnetic length free layer.

FIG. 4 depicts another exemplary embodiment of a dual magnetic junction usable in a magnetic devices and having a reduced magnetic length free layer.

FIG. 5 depicts another exemplary embodiment of a dual magnetic junction usable in a magnetic devices and having a reduced magnetic length free layer.

FIG. 6 depicts another exemplary embodiment of a dual magnetic junction usable in a magnetic devices and having a reduced magnetic length free layer.

FIG. 7 depicts another exemplary embodiment of a dual magnetic junction usable in a magnetic devices such as a magnetic memory programmable using spin transfer torque and having a reduced magnetic length free layer.

FIG. 8 depicts another exemplary embodiment of a dual magnetic junction usable in a magnetic devices such as a magnetic memory programmable using spin transfer torque and having a reduced magnetic length free layer.

FIG. 9 depicts another exemplary embodiment of a dual magnetic junction usable in a magnetic devices such as a magnetic memory programmable using spin transfer torque and having a reduced magnetic length free layer.

FIG. 10 is a flow chart depicting an exemplary embodiment of a method for providing a dual magnetic junction usable in a magnetic devices such as a magnetic memory programmable using spin transfer torque and having a reduced magnetic length free layer.

FIG. 11 is a flow chart depicting another exemplary embodiment of a method for providing a dual magnetic junction usable in a magnetic devices such as a magnetic memory programmable using spin transfer torque and having a reduced magnetic length free layer.

FIGS. 12-16 depict another exemplary embodiment of a dual magnetic junction having a reduced magnetic length free layer during fabrication.

FIG. 17 is a flow chart depicting another exemplary embodiment of a method for providing a dual magnetic junction usable in a magnetic devices such as a magnetic memory programmable using spin transfer torque and having a reduced magnetic length free layer.

FIGS. 18-20 depict another exemplary embodiment of a dual magnetic junction having a reduced magnetic length free layer during fabrication.

FIG. 21 depicts an exemplary embodiment of a memory utilizing magnetic junctions in the memory element(s) of the storage cell(s).

### DETAILED DESCRIPTION OF THE INVENTION

The exemplary embodiments relate to magnetic junctions usable in magnetic devices, such as magnetic memories, and the devices using such magnetic junctions. The magnetic memories may include spin transfer torque magnetic random access memories (STT-MRAMs) and may be used in electronic devices employing nonvolatile memory. Such electronic devices include but are not limited to cellular phones, smart phones, tables, laptops and other portable and non-portable computing devices. The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular methods and systems provided in particular implementations. However, the methods and systems will operate effectively in other implementations. Phrases such as “exemplary embodiment”, “one embodiment” and “another embodiment” may refer to the same or different embodiments as well as to multiple embodiments. The embodiments will be described with respect to systems and/or devices having certain components. However, the systems and/or devices may include more or less components than those shown, and variations in the arrangement and type of the components may be made without departing from the scope of the invention. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein.

A magnetic junction and method for providing the magnetic junction are described. The magnetic junction is usable in a magnetic device. The magnetic junction includes a free layer, first and second reference layers, and first and second nonmagnetic spacer layers. The free layer is switchable between stable magnetic states using a write current passed through the magnetic junction. The first nonmagnetic spacer layer is between the first reference layer and the free layer. The second nonmagnetic spacer layer is between the free layer and the second reference layer. The free layer is between the first nonmagnetic spacer layer and the second nonmagnetic spacer layer. The first reference layer has a first reference layer magnetic length. The second reference layer has a second reference layer magnetic length. The free layer has a free layer magnetic length less than the first reference layer magnetic length and less than the second reference layer magnetic length. The free layer magnetic length has a first end and a second end opposite to the first end. The free layer and the first reference layer are oriented such that the first reference layer magnetic length extends past the first end and past the second end of the free layer. The free layer and the second reference layer are oriented such that the second reference layer magnetic length extends past the first end and past the second end of the free layer.

The exemplary embodiments are described in the context of particular methods, magnetic junctions and magnetic memories having certain components. One of ordinary skill in the art will readily recognize that the present invention is consistent with the use of magnetic junctions and magnetic memories having other and/or additional components and/or other features not inconsistent with the present invention. The method and system are also described in the context of current understanding of the spin transfer phenomenon, of magnetic anisotropy, and other physical phenomenon. Consequently, one of ordinary skill in the art will readily recognize that theoretical explanations of the behavior of the method and system are made based upon this current understanding of spin transfer, magnetic anisotropy and other physical phenomena. However, the method and system described herein are not dependent upon a particular physical explanation. One of ordinary skill in the art will also readily recognize that the method and system are described in the context of a structure having a particular relationship to the substrate. However, one of ordinary skill in the art will readily recognize that the method and system are consistent with other structures. In addition, the method and system are described in the context of certain layers being synthetic and/or simple. However, one of ordinary skill in the art will readily recognize that the layers could have another structure. Furthermore, the method and system are described in the context of magnetic junctions and/or substructures having particular layers. However, one of ordinary skill in the art will readily recognize that magnetic junctions and/or substructures having additional and/or different layers not inconsistent with the method and system could also be used. Moreover, certain components are described as being magnetic, ferromagnetic, and ferrimagnetic. As used herein, the term magnetic could include ferromagnetic, ferrimagnetic or like structures. Thus, as used herein, the term “magnetic” or “ferromagnetic” includes, but is not limited to ferromagnets and ferrimagnets. As used herein, “in-plane” is substantially within or parallel to the plane of one or more of the layers of a magnetic junction. Conversely, “perpendicular” and “perpendicular-to-plane” corresponds to a direction that is substantially perpendicular to one or more of the layers of the magnetic junction. The method and system are also described in the context of certain alloys. Unless otherwise specified, if specific concentrations of the alloy are not mentioned, any stoichiometry not inconsistent with the method and system may be used.

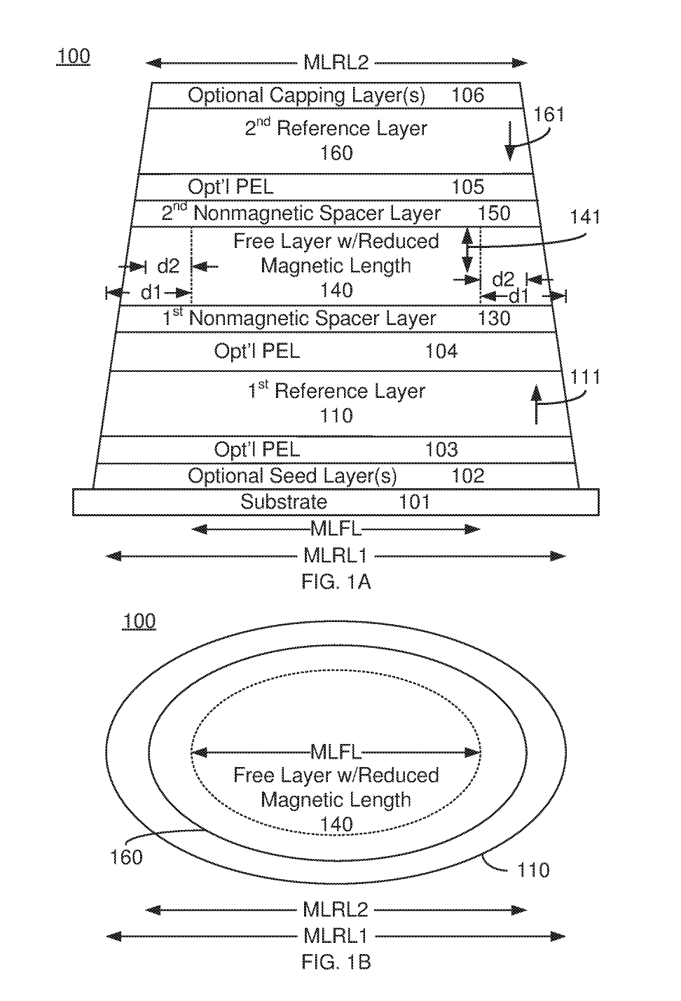

FIGS. 1A-1B depict an exemplary embodiment of a dual magnetic junction 100 usable in a magnetic devices such as a magnetic memory programmable using spin transfer torque and having a reduced magnetic length free layer. For clarity, FIGS. 1A-1B are not to scale. The magnetic junction 100 may be used in a magnetic device such as a spin transfer torque magnetic random access memory (STT-MRAM) and, therefore, in a variety of electronic devices. The magnetic junction 100 may include a first reference layer 110 having a magnetic moment 111, a first nonmagnetic spacer layer 130, a free layer 140 having magnetic moment 141, a second nonmagnetic spacer layer 150, and a second reference layer 160 having magnetic moment 161. The magnetic junction 100 may also include one or more polarization enhancement layers (PELs) 103, 104 and 105. The PELs 103, 104 and/or 105 may include CoFeB, CoFeC and/or a similar material. In other embodiments, some or all of the PELs 103, 104 and 105 may be omitted or additional PELs may be employed. Also shown are optional seed layer(s) 102 and capping layer(s) 106. The substrate 101 on which the magnetic junction 100 is formed resides below the seed layers. A bottom contact and a top contact are not shown but may be formed. Similarly, other layers may be present but are not shown for simplicity. For example, one or more texture blocking coupling layer(s) (not shown in FIGS. 1A-1B) may be present between the PEL(s) and the reference layers 110 and 160. Such texture blocking coupling layers may include Ta, W, Mo, Nb and/or another analogous material.

As can be seen in FIG. 1A, the magnetic junction 100 is a dual magnetic junction. In other embodiments, optional pinning layer(s) (not shown) may be used to fix the magnetization of the reference layer(s) 110 and/or 160. In some embodiments, the optional pinning layer may be an AFM layer or multilayer that pins the magnetization(s) through an exchange-bias interaction. However, in other embodiments, the optional pinning layer may be omitted or another structure may be used. In the embodiment shown, the magnetic moments 111 and 161 of the reference layers 110 and 160, respectively, are pinned by the magnetic anisotropy of the layers 110 and 160, respectively. The free layer 140 and the reference layers 110 and 160 have a high perpendicular magnetic anisotropy. Stated differently, the perpendicular magnetic anisotropy energy exceeds the out-of-plane demagnetization energy for the layers 110, 140 and 160. Such a configuration allows for the magnetic moments 111, 141 and 161 of the layers 110, 140 and 160, respectively, to be stable perpendicular to plane. Thus, the magnetic moments of the free layer 140 and reference layer(s) 110 and 160 are stable out-of-plane. In an alternate embodiment, the magnetic moments of the layer(s) 110, 140 and/or 160 may be stable in-plane.

The magnetic junction 100 is also configured to allow the free layer magnetic moment 141 to be switched between stable magnetic states using a write current passed through the magnetic junction 100. Thus, the free layer 140 is switchable utilizing spin transfer torque when a write current is driven through the magnetic junction 100 in a current perpendicular-to-plane (CPP) direction. The direction of the magnetic moment 141 of the free layer 140 may be read by driving a read current through the magnetic junction 100.

The nonmagnetic spacer layer(s) 130 and 150 may be tunneling barrier layers. For example, the nonmagnetic spacer layer 130 and/or 150 may be a crystalline MgO tunneling barrier with a (100) orientation. For example, the tunneling barrier layers 130 and 150 may be not more than 1.5 nm thick in some embodiments. In some such embodiments, the thicknesses of the tunneling barrier layers 130 and 150 may not exceed one nanometer. In general, the tunneling barrier layers 130 and 150 are desired to have different thicknesses. Such nonmagnetic spacer layers 130 and 150 may enhance TMR of the magnetic junction 100. In other embodiments, the nonmagnetic spacer layer(s) 130 and 150 may be formed of other material(s) including but not limited to conductors.

The reference layers 110 and 160 are shown as being simple, single layers. However, in other embodiments, the reference layer(s) 110 and/or 160 may be multilayer(s). For example, the reference layer(s) 110 and/or 160 might be a synthetic antiferromagnet (SAF) including two magnetically coupled ferromagnetic layers separated by and sandwiching a nonmagnetic layer, such as Ru. The reference layer(s) 110 and/or 160 may be high perpendicular anisotropy (Hₖ) multilayer(s). For example, the reference layer 110 and/or 160 may be or include a Co/Pt, Co/Ni and/or Co/Ir multilayer. Other reference layer(s) having other structures may be used. In addition, in alternate embodiments, the reference layer 110 and/or 160 may have the magnetic moment(s) 111 and/or 161, in plane.

The free layer 140 may be a single layer or a multilayer. For example the free layer may include a CoFeB and/or other high perpendicular magnetic anisotropy layer. The free layer 140 has a reduced magnetic length in comparison to the reference layers 110 and/or 160. The magnetic length of a layer is the distance the magnetic portion of the layer extends in plane. In some embodiments, the magnetic length of interest is only along the long axis of the magnetic junction 100. However, the magnetic length may be in other direction in-plane. The magnetic length can but need not be the same as the physical length of the layer. Thus, the magnetic (or effective) length of the layer may be less than or equal to the actual length of the layer.

The difference in magnetic lengths between the free layer 140 and the reference layers 110 and 160 can be seen in FIGS. 1A-1B. The reference layer 110 has a magnetic length MLRL1 (magnetic length reference layer 1). The reference layer 160 has a magnetic length MLRL2 (magnetic length reference layer 2). For the reference layers 110 and 160 the actual, physical lengths are substantially the same as the magnetic lengths. The free layer 140 has a magnetic length MLFL (magnetic length free layer) that is indicated by dashed lines. In some embodiments, the solid line for the free layer 140 indicates the physical length. For example, if the ends of the free layer 140 are oxidized and/or otherwise made nonmagnetic, the free layer magnetic length may be less than the free layer physical length. In other embodiments, the free layer 140 may be made physically shorter than the reference layers 110 and 160. In this case, the dashed lines in FIG. 1A would represent both the end of the free layer magnetic length and the physical end of the free layer. In such embodiments, the region between the dashed lines and the solid lines may be formed of another, nonmagnetic refill material.

As can be seen in FIGS. 1A and 1 B, the magnetic lengths of both of the reference layers 110 and 160 exceed the magnetic length of the free layer 140 (MLRL1>MLFL, MLRL2>MLFL). The magnetic length of the reference layer 110 extends further than each end of the free layer magnetic length by a distance d1. The magnetic length of the reference layer 160 extends further than each end of the free layer magnetic length by a distance d2. In some embodiments, d1 and d2 are at least five nanometers. In some such embodiments, d1 and d2 do not exceed ten nanometers. For example, the free layer 140 may have a magnetic length of at least twenty-five nanometers. In such embodiments, the reference layer 160 may have a magnetic length that is at least thirty five nanometers. In some cases, the magnetic length of the reference layer 160 is not more than forty-five nanometers. The reference layer 110 may also have a magnetic length that is at least thirty-five nanometers and, in some cases, not more than forty-five nanometers. However, the magnetic lengths of the reference layers 110 and 160 need not be the same.

In the embodiment shown, the free layer magnetic length is shown as substantially centered along the magnetic lengths of the reference layers 110 and 160. Thus, the reference layer 160 has a magnetic length that extends the same distance, d2, further than the ends of the free layer magnetic length by approximately the same amount in both directions. Similarly, the reference layer 110 has a magnetic length that extends the same distance, d1, further than the ends of the free layer magnetic length in both directions shown. In other embodiments, the free layer 140 may not be centered. In such embodiments, the magnetic length of the reference layer 160 and/or 110 would extend further than the ends of the free layer magnetic length by different distances. However, in all embodiments, the reference layers 110 and 160 extend further than the ends of the magnetic length of the free layer 140.

In some embodiments, the magnetic length of the free layer 140 may also be smaller than the magnetic lengths of the reference layers 110 and 160 in other directions in-plane. For example the free layer 140 may have a reduced magnetic length in comparison to both reference layers 110 and 160 along the short axis of the magnetic junction 100. This direction is perpendicular to the page. In some embodiments, the magnetic lengths of the reference layers 110 and 160 exceeds that of the free layer 140 for multiple directions in-plane. For example, the free layer magnetic length may be less than the magnetic lengths of the reference layers 110 and 160 in all directions in-plane. Such a case is shown in FIG. 1B. The distance by which the reference layer magnetic lengths exceed the free layer magnetic length can but need not be the same in all directions.

Use of a free layer 140 having a reduced magnetic length with respect to the reference layers 110 and 160 may improve performance. Because the magnetic lengths of the reference layers 110 and 160 extend further than that of the free layer 140, any magnetic effects due to the edges of the reference layers 110 and 160 may be less likely to adversely affect performance. Near the center of the magnetic junction 100, the magnetic field on the free layer 140 due to the reference layers 110 and 160 is substantially constant, small and perpendicular-to-plane. Near the edges of the magnetic junction 100, the magnetic field due to the reference layers 110 and 160 exhibits flowering. Thus, the magnetic field is larger and has a nonzero component in-plane. At and beyond the edges of the magnetic junction 100, the in-plane component of the magnetic field may be substantial. Thus, the magnetic field “flowers” (e.g. increases in magnitude bends outward in a manner similar to petals of a flower) near the edges of the magnetic junction 100. This effect reduces the efficiency of switching. Consequently, a higher switching current is needed to write to a free layer having a magnetic length that extends to the edges of the magnetic junction 100. Because its magnetic length terminates closer to the center of the magnetic junction, the free layer 140 experiences little flowering of the field due to the reference layers 110 and 160. Stated differently, the free layer 140 experiences a smaller, more uniform perpendicular-to-plane field from the reference layers 110 and 160 because the free layer 140 magnetic length ends further from the edges of the reference layer magnetic lengths. Consequently, the free layer 140 may be written using a lower write current. Performance of the magnetic junction may thus be improved.

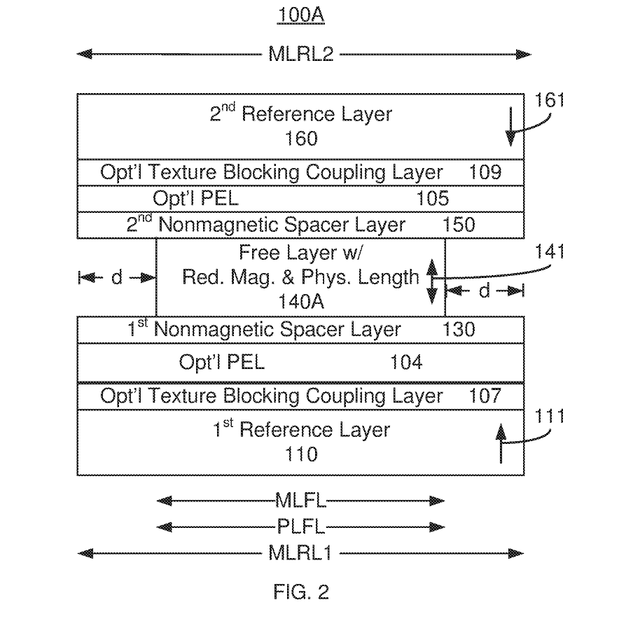

FIG. 2 depicts another exemplary embodiment of a dual magnetic junction 100A usable in a magnetic devices such as a magnetic memory programmable using spin transfer torque and having a reduced magnetic length free layer. For clarity, FIG. 2 is not to scale. The magnetic junction 100A is analogous to the magnetic junction 100. Consequently, similar components have analogous labels. For example, the magnetic junction 100A includes a reference layer 110, an optional PEL 104, a nonmagnetic spacer layer 130, a free layer 140A, another nonmagnetic spacer 150, an additional optional PEL 105 and a second reference layer 160 that are analogous to the layers 110, 104, 130, 140, 150, 105 and 160, respectively. These layers 110, 104, 130, 140A, 150, 105 and 160 have an analogous structure and function to the layers 110, 104, 130, 140, 150, 105 and 160 depicted in FIGS. 1A-1B. For example, the reference layers 110 and 160 and the free layer 140A may each have a perpendicular magnetic anisotropy that exceeds the out-of-plane demagnetization energy. Thus, the magnetic moments 111, 141 and 161 may be stable perpendicular to plane. Also shown are texture blocking coupling layers 107 and 109, which were not shown/not present in the magnetic junction 100. The sidewalls of the layers in the magnetic junction 100A are shown as vertical. However, in at least some embodiments, the sidewalls may be angled in a manner analogous to that shown in FIG. 1A. Further, although the layers 110, 107, 104, 130, 140A, 150, 105, 109 and 160 appear to be shown with the reference layer 110 being closest to the substrate. However, another order may be possible. For example, the order of the layers 110, 107, 104, 130, 140A, 150, 105, 109 and 160 may be reversed such that the reference layer 160 is closest to the substrate.

The free layer 140A has a reduced magnetic length and reduced physical length in comparison to those of the reference layers 110 and 160. The reference layers 110 and 160 have magnetic lengths MLRL1 and MLRL2, respectively. The free layer 140A has a magnetic length MLFL. In the embodiment shown, the magnetic length of the free layer 140A is substantially the same as the physical length PLFL (physical length free layer) of the free layer 140A. For the reference layers 110 and 160 the actual, physical lengths are substantially the same as the magnetic lengths. The region between the nonmagnetic spacer laser 130 and 150 may be filled with an oxide (not shown for clarity). The magnetic length of the reference layer 110 extends further than each end of the free layer magnetic length by a distance d. The magnetic length of the reference layer 160 extends further than each end of the free layer magnetic length by a distance d. In some embodiments, d has the ranges described above. Further the free layer 140A may be in the size range described above. In other embodiments, the magnetic length of the reference layer 160 and/or 110 would extend further than the ends of the free layer magnetic length by different distances.

In some embodiments, the magnetic and physical lengths of the free layer 140A may also be less than the magnetic and physical lengths of the reference layers 110 and 160 in other directions in-plane. The distance by which the reference layer magnetic lengths exceed the free layer magnetic length can but need not be the same in all directions.

Use of a free layer 140A having a reduced magnetic and physical length with respect to the reference layers 110 and 160 may improve performance. For the reasons discussed above, any magnetic effects due to the edges of the reference layers 110 and 160 may be less likely to adversely affect performance. For example, flowering of the magnetic field from the reference layers 110 and 160 may be less likely to affect performance of the free layer 140A. The free layer 140 experiences a smaller, more uniform perpendicular-to-plane field from the reference layers 110 and 160 because the free layer 140A magnetic length ends further from the edges of the reference layer magnetic lengths. Consequently, the free layer 140 may be written using a lower write current. Performance of the magnetic junction 100A may thus be improved. Further, the free layer physical length may be set using photolithographic techniques. As a result, the location of the ends of the free layer magnetic length may be more easily and reliably formed. Consequently, fabrication of the magnetic junction 100A may be improved.

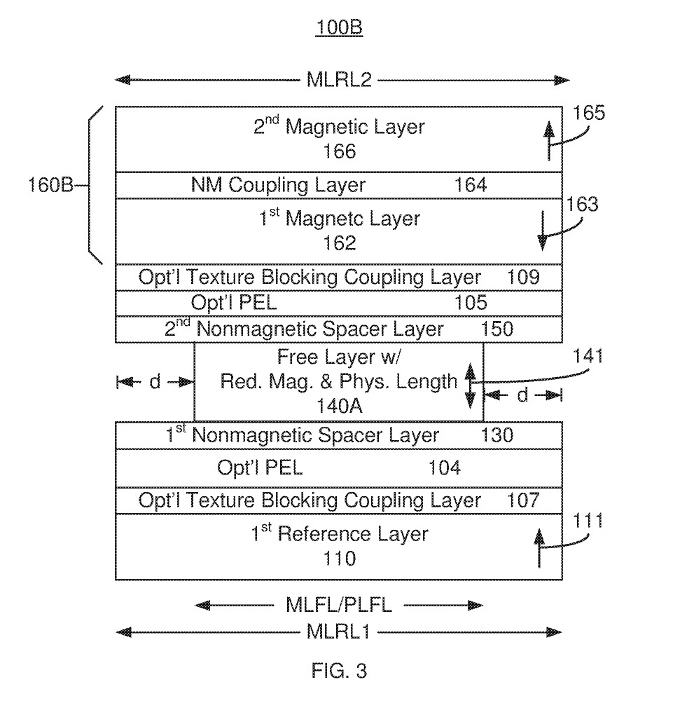

FIG. 3 depicts another exemplary embodiment of a dual magnetic junction 100B usable in a magnetic devices such as a magnetic memory programmable using spin transfer torque and having a reduced magnetic length free layer. For clarity, FIG. 3 is not to scale. The magnetic junction 100B is analogous to the magnetic junctions 100 and 100A. Consequently, similar components have analogous labels. For example, the magnetic junction 100B includes a reference layer 110, an optional texture blocking coupling layer 107, an optional PEL 104, a nonmagnetic spacer layer 130, a free layer 140A, another nonmagnetic spacer 150, an additional optional PEL 105, optional texture blocking coupling layer 109 and a second reference layer 160B that are analogous to the layers 110, 107, 104, 130, 140/140A, 150, 105, 109 and 160, respectively. These layers 110, 107, 104, 130, 140A, 150, 105, 109 and 160B have an analogous structure and function to the layers 110, 107, 104, 130, 140/140A, 150, 105, 109 and 160 depicted in FIGS. 1A-2. For example, the reference layers 110 and 160B and the free layer 140A may each have a perpendicular magnetic anisotropy that exceeds the out-of-plane demagnetization energy. Thus, the magnetic moments 111, 141, 163 and 165 may be stable perpendicular to plane. The sidewalls of the layers in the magnetic junction 100B are shown as vertical. However, in at least some embodiments, the sidewalls may be angled in a manner analogous to that shown in FIG. 1A. Further, although the layers 110, 107, 104, 130, 140A, 150, 105, 109 and 160B appear to be shown with the reference layer 110 being closest to the substrate. However, another order may be possible. For example, the order of the layers 110, 107, 104, 130, 140A, 150, 105, 109 and 160B may be reversed such that the reference layer 160B is closest to the substrate.

The free layer 140A has a reduced magnetic length and reduced physical length in comparison to those of the reference layers 110 and 160B. Thus the free layer 140A is analogous to that described above. The reference layer 160B a SAF including magnetic layers 162 and 166 separated by nonmagnetic coupling layer 164. For example the magnetic layer(s) 162 and/or 166 may include a Co/Pt multilayer, a Co/Ni multilayer, a Co/Ir multilayer and/or another multilayer or alloy. The nonmagnetic coupling layer 164 moderates the magnetic coupling between the magnetic layers 162 and 166. In the embodiment shown, the magnetic layers 162 and 166 are antiferromagnetically coupled, for example via an RKKY interaction. Thus, the magnetic moments 163 and 165 are antiparallel.

The magnetic junction 100B may share the benefits of the magnetic junctions 100 and/or 100A. The free layer 140A may be written using a lower write current. Performance of the magnetic junction 100B may thus be improved. Further, the free layer physical length may be set using photolithographic techniques. Consequently, fabrication of the magnetic junction 100B may be improved.

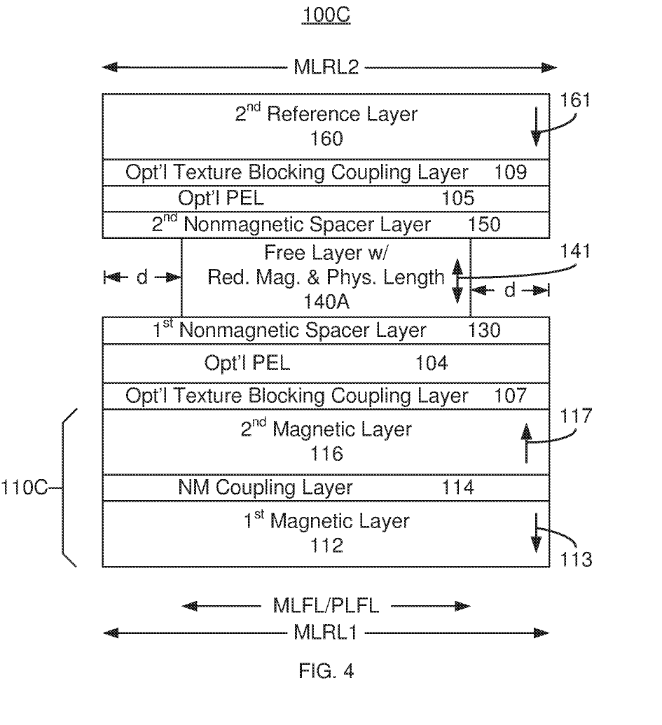

FIG. 4 depicts another exemplary embodiment of a dual magnetic junction 100C usable in a magnetic devices such as a magnetic memory programmable using spin transfer torque and having a reduced magnetic length free layer. For clarity, FIG. 4 is not to scale. The magnetic junction 100C is analogous to the magnetic junctions 100, 100A and/or 100B. Consequently, similar components have analogous labels. For example, the magnetic junction 100C includes a reference layer 110C, an optional texture blocking coupling layer 107, an optional PEL 104, a nonmagnetic spacer layer 130, a free layer 140A, another nonmagnetic spacer 150, an additional optional PEL 105, optional texture blocking coupling layer 109 and a second reference layer 160 that are analogous to the layers 110, 107, 104, 130, 140/140A, 150, 105, 109 and 160, respectively. These layers 110C, 107, 104, 130, 140A, 150, 105, 109 and 160 have an analogous structure and function to the layers 110, 107, 104, 130, 140/140A, 150, 105, 109 and 160 depicted in FIGS. 1A-3. For example, the reference layers 110C and 160 and the free layer 140A may each have a perpendicular magnetic anisotropy that exceeds the out-of-plane demagnetization energy. Thus, the magnetic moments 113, 117, 141 and 161 may be stable perpendicular to plane. The sidewalls of the layers in the magnetic junction 100C are shown as vertical. However, in at least some embodiments, the sidewalls may be angled in a manner analogous to that shown in FIG. 1A. Further, although the layers 110C, 107, 104, 130, 140A, 150, 105, 109 and 160 appear to be shown with the reference layer 110C being closest to the substrate. However, another order may be possible. For example, the order of the layers 110C, 107, 104, 130, 140A, 150, 105, 109 and 160 may be reversed such that the reference layer 160 is closest to the substrate.

The free layer 140A has a reduced magnetic length and reduced physical length in comparison to those of the reference layers 110C and 160. Thus the free layer 140A is analogous to that described above. The reference layer 110C is a SAF including magnetic layers 112 and 116 separated by nonmagnetic coupling layer 114. For example the magnetic layer(s) 112 and/or 116 may include a Co/Pt multilayer, a Co/Ni multilayer, a Co/Ir multilayer and/or another multilayer or alloy. The nonmagnetic coupling layer 114 moderates the magnetic coupling between the magnetic layers 112 and 116. In the embodiment shown, the magnetic layers 112 and 116 are antiferromagnetically coupled, for example via an RKKY interaction. Thus, the magnetic moments 113 and 117 are antiparallel. The magnetic junction 100C may be viewed as the same as the magnetic junction 100B, with the order of layers reversed.

The magnetic junction 100C may share the benefits of the magnetic junctions 100, 100A and/or 100B. The free layer 140A may be written using a lower write current. Performance of the magnetic junction 100C may thus be improved. Further, the free layer physical length may be set using photolithographic techniques. Consequently, fabrication of the magnetic junction 100C may be improved.

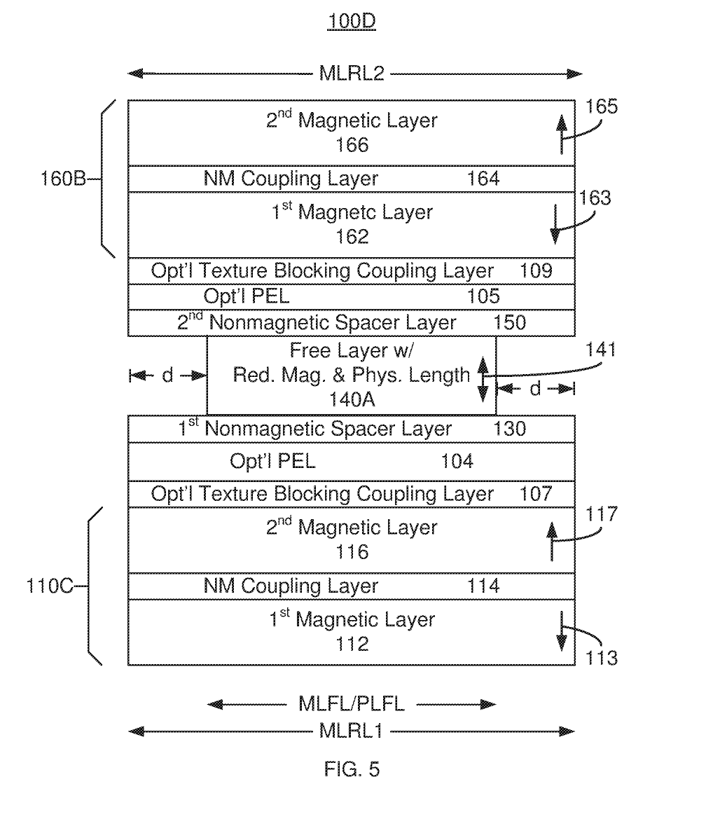

FIG. 5 depicts another exemplary embodiment of a dual magnetic junction 100D usable in a magnetic devices such as a magnetic memory programmable using spin transfer torque and having a reduced magnetic length free layer. For clarity, FIG. 5 is not to scale. The magnetic junction 100D is analogous to the magnetic junctions 100, 100A, 100B and/or 100C. Consequently, similar components have analogous labels. For example, the magnetic junction 100D includes a reference layer 110C, an optional texture blocking coupling layer 107, an optional PEL 104, a nonmagnetic spacer layer 130, a free layer 140A, another nonmagnetic spacer 150, an additional optional PEL 105, optional texture blocking coupling layer 109 and a second reference layer 160B that are analogous to the layers 110/110C, 107, 104, 130, 140/140A, 150, 105, 109 and 160/160B, respectively. These layers 110C, 107, 104, 130, 140A, 150, 105, 109 and 160B have an analogous structure and function to the layers 110/110C, 107, 104, 130, 140/140A, 150, 105, 109 and 160/160B depicted in FIGS. 1A-4. For example, the reference layers 110C and 160B and the free layer 140A may each have a perpendicular magnetic anisotropy that exceeds the out-of-plane demagnetization energy. Thus, the magnetic moments 113, 117, 141, 163 and 165 may be stable perpendicular to plane. The sidewalls of the layers in the magnetic junction 100D are shown as vertical. However, in at least some embodiments, the sidewalls may be angled in a manner analogous to that shown in FIG. 1A. Further, although the layers 110C, 107, 104, 130, 140A, 150, 105, 109 and 160B appear to be shown with the reference layer 110C being closest to the substrate. However, another order may be possible. For example, the order of the layers 110C, 107, 104, 130, 140A, 150, 105, 109 and 160B may be reversed such that the reference layer 160B is closest to the substrate.

The free layer 140A has a reduced magnetic length and reduced physical length in comparison to those of the reference layers 110C and 160B. Thus the free layer 140A is analogous to that described above. Both reference layers 110C and 160B are SAFs. The reference layer 110C includes magnetic layers 112 and 116 separated by nonmagnetic coupling layer 114. The reference layer 160B includes magnetic layers 162 and 166 separated by nonmagnetic coupling layer 164. The layers 112 114 116, 162, 164 and 166 are analogous to those described above.

The magnetic junction 100D may share the benefits of the magnetic junctions 100, 100A, 100B and/or 100C. The free layer 140A may be written using a lower write current. Performance of the magnetic junction 100D may thus be improved. Further, the free layer physical length may be set using photolithographic techniques. Consequently, fabrication of the magnetic junction 100D may be improved.

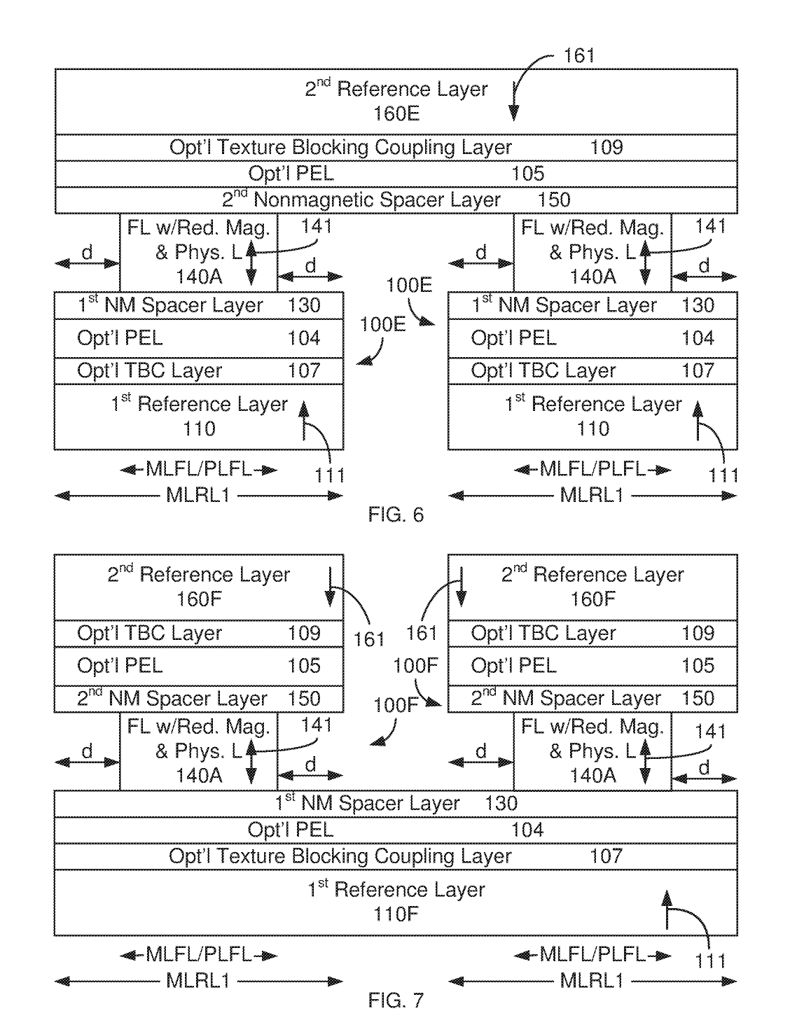

FIG. 6 depicts another exemplary embodiment of two dual magnetic junctions 100E usable in magnetic devices such as a magnetic memory programmable using spin transfer torque and having a reduced magnetic length free layer. For clarity, FIG. 6 is not to scale. The magnetic junction 100E is analogous to the magnetic junctions 100, 100A, 100B, 100C and/or 100D. Consequently, similar components have analogous labels. For example, the magnetic junction 100E includes a reference layer 110, an optional texture blocking coupling layer 107, an optional PEL 104, a nonmagnetic spacer layer 130, a free layer 140A, another nonmagnetic spacer 150, an additional optional PEL 105, optional texture blocking coupling layer 109 and a second reference layer 160E that are analogous to the layers 110/110C, 107, 104, 130, 140/140A, 150, 105, 109 and 160/160B, respectively. These layers 110, 107, 104, 130, 140A, 150, 105, 109 and 160E have an analogous structure and function to the layers 110/110C, 107, 104, 130, 140/140A, 150, 105, 109 and 160/160B depicted in FIGS. 1A-5. For example, the reference layers 110 and 160E and the free layer 140A may each have a perpendicular magnetic anisotropy that exceeds the out-of-plane demagnetization energy. Thus, the magnetic moments 111, 141 and 161 may be stable perpendicular to plane. The sidewalls of the layers in the magnetic junction 100E are shown as vertical. However, in at least some embodiments, the sidewalls may be angled in a manner analogous to that shown in FIG. 1A. Further, although the layers 110, 107, 104, 130, 140A, 150, 105, 109 and 160E appear to be shown with the reference layer 110 being closest to the substrate. However, another order may be possible. For example, the order of the layers 110, 107, 104, 130, 140A, 150, 105, 109 and 160E may be reversed such that the reference layer 160E is closest to the substrate. Although depicted as simple (single) layers, the layers 110, 140A and/or 160E may be multilayers. For example the layers 110 and/or 160E may be SAFs such as the layers 110C and 160B, respectively.

The free layer 140A has a reduced magnetic length and reduced physical length in comparison to those of the reference layers 110 and 160E. Thus the free layer 140A is analogous to that described above. In addition, the second reference layer 160E is an extended reference layer that forms part of at least two magnetic junctions 100E. In the embodiment shown, the nonmagnetic spacer layer 150, optional PEL 105 and optional texture blocking coupling layer 109 also extend across multiple magnetic junctions 100E.

The magnetic junction 100E may share the benefits of the magnetic junctions 100, 100A, 100B, 100C and/or 100D. The free layer 140A may be written using a lower write current. Performance of the magnetic junction 100E may thus be improved. Further, the free layer physical length may be set using photolithographic techniques. Consequently, fabrication of the magnetic junction 100E may be improved. Moreover, the reference layer 160E need not be patterned. Fabrication of the magnetic junction 100E may thus be further simplified.

FIG. 7 depicts another exemplary embodiment of two dual magnetic junctions 100F usable in magnetic devices such as a magnetic memory programmable using spin transfer torque and having a reduced magnetic length free layer. For clarity, FIG. 7 is not to scale. The magnetic junction 100F is analogous to the magnetic junctions 100, 100A, 100B, 100C, 100D and/or 100E. Consequently, similar components have analogous labels. For example, the magnetic junction 100F includes a reference layer 110F, an optional texture blocking coupling layer 107, an optional PEL 104, a nonmagnetic spacer layer 130, a free layer 140A, another nonmagnetic spacer 150, an additional optional PEL 105, optional texture blocking coupling layer 109 and a second reference layer 160 that are analogous to the layers 110/110C, 107, 104, 130, 140/140A, 150, 105, 109 and 160/160B/160E, respectively. These layers 110F, 107, 104, 130, 140A, 150, 105, 109 and 160 have an analogous structure and function to the layers 110/110C, 107, 104, 130, 140/140A, 150, 105, 109 and 160/160B/160E depicted in FIGS. 1A-6. For example, the reference layers 110F and 160 and the free layer 140A may each have a perpendicular magnetic anisotropy that exceeds the out-of-plane demagnetization energy. Thus, the magnetic moments 111, 141 and 161 may be stable perpendicular to plane. The sidewalls of the layers in the magnetic junction 100F are shown as vertical. However, in at least some embodiments, the sidewalls may be angled in a manner analogous to that shown in FIG. 1A. Further, although the layers 110F, 107, 104, 130, 140A, 150, 105, 109 and 160 appear to be shown with the reference layer 110F being closest to the substrate. However, another order may be possible. For example, the order of the layers 110F, 107, 104, 130, 140A, 150, 105, 109 and 160 may be reversed such that the reference layer 160 is closest to the substrate. Although depicted as simple (single) layers, the layers 110F, 140A and/or 160 may be multilayers. For example the layers 110F and/or 160 may be SAFs such as the layers 110C and 160B, respectively.

The free layer 140A has a reduced magnetic length and reduced physical length in comparison to those of the reference layers 110F and 160. Thus the free layer 140A is analogous to that described above. In addition, the first reference layer 110F is an extended reference layer that forms part of at least two magnetic junctions 100F. In the embodiment shown, the nonmagnetic spacer layer 130, optional PEL 104 and optional texture blocking coupling layer 107 also extend across multiple magnetic junctions 100F.

The magnetic junction 100F may share the benefits of the magnetic junctions 100, 100A, 100B, 100C 100D and/or 100E. The free layer 140A may be written using a lower write current. Performance of the magnetic junction 100F may thus be improved. Further, the free layer physical length may be set using photolithographic techniques. Consequently, fabrication of the magnetic junction 100E may be improved. Moreover, the reference layer 110F need not be patterned. Fabrication of the magnetic junction 100F may thus be further simplified.

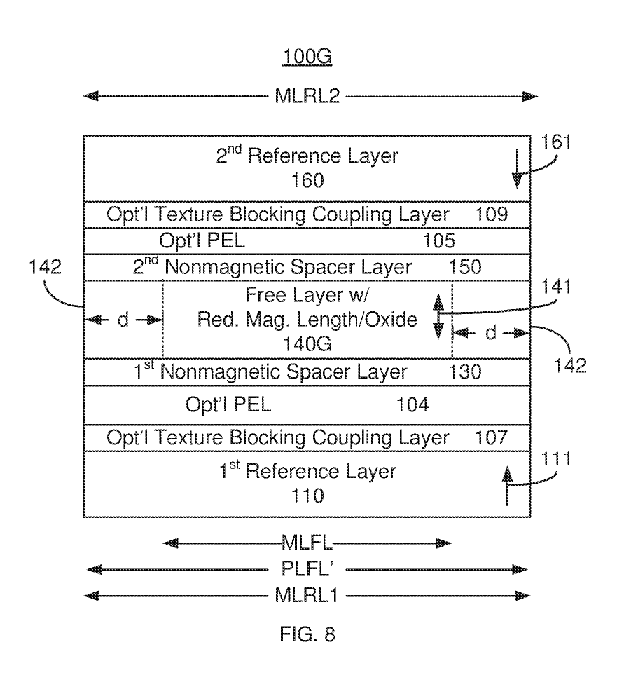

FIG. 8 depicts another exemplary embodiment of a dual magnetic junction 100G usable in a magnetic devices such as a magnetic memory programmable using spin transfer torque and having a reduced magnetic length free layer. For clarity, FIG. 8 is not to scale. The magnetic junction 100G is analogous to the magnetic junctions 100, 100A, 100B, 100C, 100D, 100E and/or 100F. Consequently, similar components have analogous labels. For example, the magnetic junction 100G includes a reference layer 110, an optional texture blocking coupling layer 107, an optional PEL 104, a nonmagnetic spacer layer 130, a free layer 140G, another nonmagnetic spacer 150, an additional optional PEL 105, optional texture blocking coupling layer 109 and a second reference layer 160 that are analogous to the layers 110/110C/110F, 107, 104, 130, 140/140A, 150, 105, 109 and 160/160B/160E, respectively. These layers 110, 107, 104, 130, 140F, 150, 105, 109 and 160 have an analogous structure and function to the layers 110/110C/110F, 107, 104, 130, 140/140A, 150, 105, 109 and 160/160B/160E depicted in FIGS. 1A-7. For example, the reference layers 110 and 160 and the free layer 140G may each have a perpendicular magnetic anisotropy that exceeds the out-of-plane demagnetization energy. Thus, the magnetic moments 111, 141 and 161 may be stable perpendicular to plane. The sidewalls of the layers in the magnetic junction 100G are shown as vertical. However, in at least some embodiments, the sidewalls may be angled in a manner analogous to that shown in FIG. 1A. Further, although the layers 110, 107, 104, 130, 140G, 150, 105, 109 and 160 appear to be shown with the reference layer 110 being closest to the substrate. However, another order may be possible. For example, the order of the layers 110, 107, 104, 130, 140G, 150, 105, 109 and 160 may be reversed such that the reference layer 160 is closest to the substrate. Although depicted as simple (single) layers, the layers 110, 140G and/or 160 may be multilayers. For example the layers 110 and/or 160 may be SAFs such as the layers 110C and 160B, respectively.

The free layer 140G has a reduced magnetic length in comparison to those of the reference layers 110 and 160. The reference layers 110 and 160 have magnetic lengths MLRL1 and MLRL2, respectively. The free layer 140G has a magnetic length MLFL, which is shown by dashed lines. However, the physical length PLFL′ of the free layer 140G is greater than the magnetic length. This difference between the magnetic and physical lengths may be achieved by oxidizing the edges of the free layer 140G. For example, the free layer 140G may include a material, such as Mg, that has a higher affinity for oxygen than the magnetic materials used in the free layer 140G. Other higher oxygen affinity materials that may be used include Al, Ti, Ta, W, Zr and/or V. In some embodiments, the free layer 140G includes at least five atomic percent and not more than fifteen atomic percent of the high oxygen affinity material(s). Upon exposure to an oxygen plasma or analogous oxidizing process, the edges of the free layer 140G oxidize. Thus, the magnetic length is made shorter than the physical length. In contrast, the physical lengths are substantially the same as the magnetic lengths for the reference layers 110 and 160. The magnetic lengths of the reference layers 110 and 160 extend further than each end of the free layer magnetic length by a distance d. In other embodiments, the magnetic length of the reference layer 160 and/or 110 would extend further than the ends of the free layer magnetic length by different distances. In some embodiments, the magnetic length of the free layer 140G may also be less than the magnetic lengths of the reference layers 110 and 160 in other directions in-plane. The distance by which the reference layer magnetic lengths exceed the free layer magnetic length can but need not be the same in all directions.

Use of a free layer 140G having a reduced magnetic with respect to the reference layers 110 and 160 may improve performance. For the reasons discussed above, any magnetic effects due to the edges of the reference layers 110 and 160 may be less likely to adversely affect performance. For example, flowering of the magnetic field from the reference layers 110 and 160 may be less likely to affect performance of the free layer 140G. Instead, the free layer 140 experiences a more uniform perpendicular-to-plane field from the reference layers 110 and 160 because the free layer 140G magnetic length ends further from the edges of the reference layer magnetic lengths. Consequently, the free layer 140 may be written using a lower write current. Performance of the magnetic junction 100G may thus be improved.

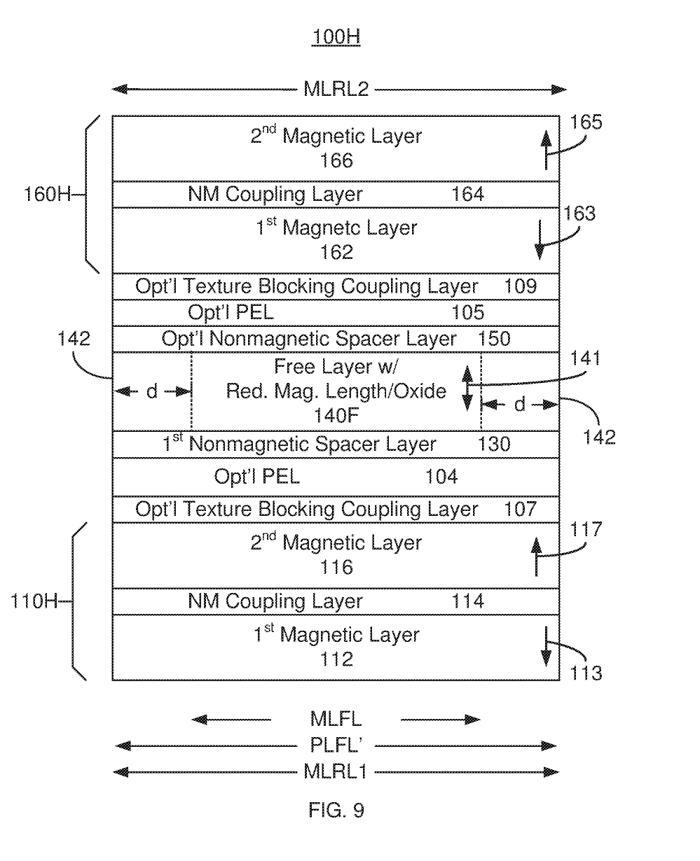

FIG. 9 depicts another exemplary embodiment of a dual magnetic junction 100H usable in a magnetic devices such as a magnetic memory programmable using spin transfer torque and having a reduced magnetic length free layer. For clarity, FIG. 9 is not to scale. The magnetic junction 100H is analogous to the magnetic junctions 100, 100A, 100B, 100C, 100D, 100E, 100F and/or 100G. Consequently, similar components have analogous labels. For example, the magnetic junction 100H includes a reference layer 110H, an optional texture blocking coupling layer 107, an optional PEL 104, a nonmagnetic spacer layer 130, a free layer 140G, another nonmagnetic spacer 150, an additional optional PEL 105, optional texture blocking coupling layer 109 and a second reference layer 160H that are analogous to the layers 110/110C/110F, 107, 104, 130, 140/140A/140G, 150, 105, 109 and 160/160B/160E, respectively. These layers 110H, 107, 104, 130, 140A, 150, 105, 109 and 160H have an analogous structure and function to the layers 110/110C/110F, 107, 104, 130, 140/140A, 150, 105, 109 and 160/160B/160E depicted in FIGS. 1A-8. For example, the reference layers 110H and 160H and the free layer 140G may each have a perpendicular magnetic anisotropy that exceeds the out-of-plane demagnetization energy. Thus, the magnetic moments 113, 117, 141, 163 and 165 may be stable perpendicular to plane. The sidewalls of the layers in the magnetic junction 100H are shown as vertical. However, in at least some embodiments, the sidewalls may be angled in a manner analogous to that shown in FIG. 1A. Further, although the layers 110H, 107, 104, 130, 140G, 150, 105, 109 and 160H appear to be shown with the reference layer 110H being closest to the substrate. However, another order may be possible. For example, the order of the layers 110H, 107, 104, 130, 140G, 150, 105, 109 and 160H may be reversed such that the reference layer 160H is closest to the substrate. The reference layers 110H and 160H are both shown as SAFs. Thus, the reference layer 110H includes magnetic layers 112 and 116 separated by nonmagnetic coupling layer 114. Similarly, the reference layer 160H incudes magnetic layers 162 and 166 separated by nonmagnetic coupling layer 164. However, in other embodiments, one or both of the layers 110H and/or 160H may have a different structure. In addition, one or both of the layers 110H and/or 160H may be an extended reference layer analogous to the layers 110F and/or 160E.

The free layer 140G has a reduced magnetic length in comparison to that of the reference layers 110H and 160H. Thus the free layer 140G is analogous to that described above. In addition, the reference layers 110H and/or 160H may be configured in a manner analogous to the reference layer(s) of one or more of the magnetic junctions 100, 100A, 100B, 100C, 100D, 100E, 100F and/or 100G.

The magnetic junction 100H may share the benefits of the magnetic junctions 100, 100A, 100B, 100C, 100D, 100E, 100F and/or 100G. The free layer 140G may be written using a lower write current. Performance of the magnetic junction 100G may thus be improved.

Various features have been described with respect to the magnetic junctions 100, 100A, 100B, 100C, 100D, 100E, 100F, 100G and/or 100H. One of ordinary skill in the art will recognize that these features may be combined in manner(s) not shown and which are not inconsistent with the devices and methods described herein.

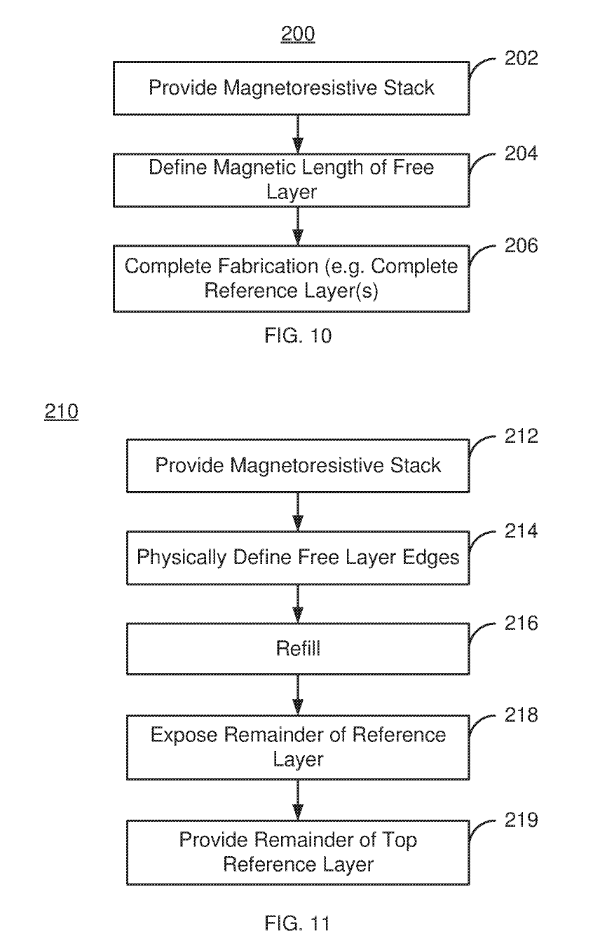

FIG. 10 is a flow chart depicting an exemplary embodiment of a method 200 for providing a layer for magnetic junction usable in a magnetic device and including a free layer having a reduced magnetic length. For simplicity, some steps may be omitted, performed in another order, include substeps and/or combined. Further, the method 200 start after other steps in forming a magnetic memory have been performed. The method 200 is described in the context of the magnetic junctions 100, 100A, 100B, 100C, 100D, 100E, 100F, 100G and/or 100H. However the method 200 may be used in forming other magnetic junction(s). Further, multiple magnetic junctions may be simultaneously fabricated.

A magnetoresistive stack for the magnetic junction(s) 100, 100A, 100B, 100C, 100D, 100E, 100F, 100G and/or 100H is provided, via step 202. Step 202 includes depositing at least a first fixed magnetic layer for the reference layer 110/110C/110F/110H, depositing a first nonmagnetic layer for the nonmagnetic spacer layer 130, depositing a free magnetic layer for the free layer 140/140A/140G, depositing a second nonmagnetic layer for the nonmagnetic spacer layer 150 and depositing a second fixed magnetic layer for the reference layer 160/160B/160E/160H.

The free layer magnetic length MLFL for the free layer 140/140A/140G is defined, via step 204. Step 204 includes ensuring that the free layer magnetic length is less than the magnetic lengths of the reference layers 110/110C/110F/110H and 160/160B/160E/160H. For example, step 204 may include masking the region corresponding to the desired magnetic length of the free layer 140/140A and removing the exposed portion of the free magnetic layer and any layers above the free magnetic layer. Alternatively, step 204 may include masking the region corresponding to the desired physical length of the reference layer(s) 110/110C/110F/110H and 160/160B/160E/160H, removing the exposed portion of the magnetoresistive stack and then oxidizing the edges of the free layer 140/140G. Thus, the magnetic length MLFL of the free layer 140, 140A and/or 140G is defined.

Fabrication of the magnetic junction(s) 100, 100A, 100B, 100C, 100D, 100E, 100F, 100G and/or 100H is completed, via step 206. Step 206 may include refilling the region around the free layer 140/140A or around the magnetic junction with an insulator. If the free layer 140A is being formed, then step 206 may include not only refilling the region around the free layer 140A with an insulator, but also depositing an additional portion of the second reference layer 160/160B/160E. If the free layer 140G is being formed, then step 206 may include other steps. In addition, step 206 may also be used to manufacture other portions of the device in which the magnetic junction 100, 100A, 100B, 100C, 100D, 100E, 100F, 100G and/or 100H is to be used. For example, capping layers, contacts, or other structures might be formed.

Using the method 200, the magnetic junction(s) 100, 100A, 100B, 100C, 100D, 100E, 100F, 100G and/or 100H may be formed. The free layers 140, 140A and/or 140H may be fabricated with shorter magnetic lengths. As a result, a magnetic junction having free layer(s) with improved switching characteristics may be achieved.

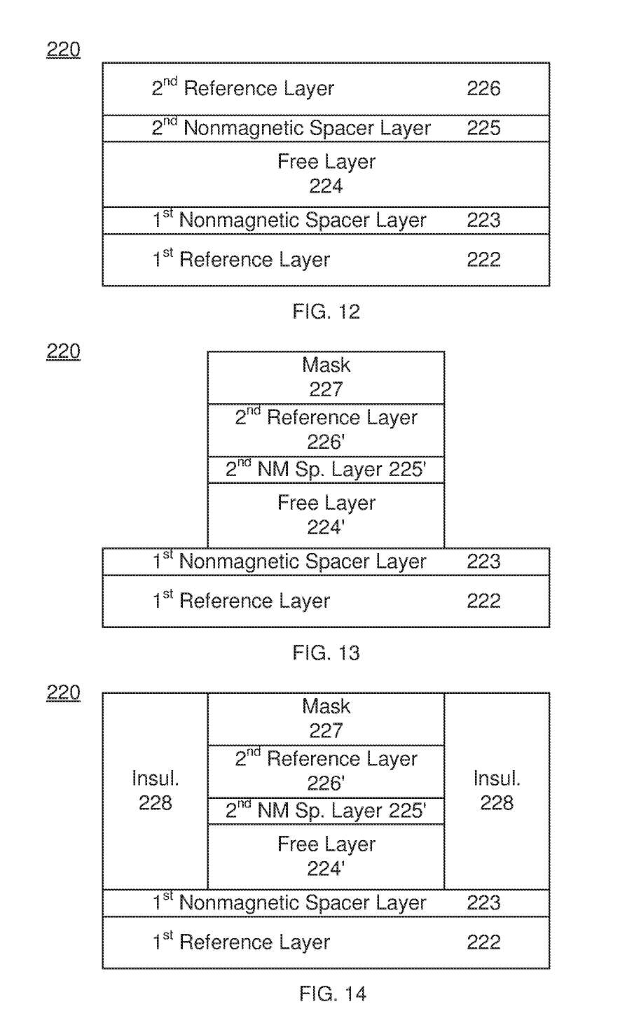

FIG. 11 is a flow chart depicting an exemplary embodiment of a method 210 for providing a layer for magnetic junction usable in a magnetic device and including a free layer having reduced magnetic and physical lengths. For simplicity, some steps may be omitted, performed in another order, include substeps and/or combined. FIGS. 12-16 depict an exemplary embodiment of a magnetic junction 220 during fabrication using the method 210. For clarity, only the reference layers, free layer and nonmagnetic spacer layers are shown in FIGS. 12-16. However, other layers including but not limited to PEL(s), texture blocking coupling layer(s) and/or other layers may be included. The method 210 is thus described in the context of the magnetic junction 220. However the method 210 may be used in forming other magnetic junction(s). Further, multiple magnetic junctions may be simultaneously fabricated. Further, the method 210 may start after other steps in forming a magnetic memory have been performed.

A magnetoresistive stack for the magnetic junction 220 is provided, via step 212. FIG. 12 depicts the magnetic junction 220 after step 212 is performed. Thus, layers for the first reference layer 222, first nonmagnetic spacer layer 223, free layer 224, second nonmagnetic spacer layer 225 and second reference layer 226 have been deposited. Providing each layer 222, 223, 224, 225 and 226 may include multiple substeps. For example, one or more multilayers may be deposited as part of providing the materials for the first reference layer 222. The materials for the layers 222, 223, 224, 225 and 226 are analogous to those described above for the magnetic junctions 100, 100A, 100B, 100C, 100D, 100E, and 100F.

The edges of the free layer are physically defined, via step 214. Step 214 may include providing a mask covering the region corresponding to the desired magnetic length of the free layer and removing the exposed portion of the free layer 224 and any layers above the free magnetic layer 224. This removal may include an ion mill or reactive ion etch (RIE) which stops at or within the first nonmagnetic spacer layer 223. FIG. 13 depicts the magnetic junction 220 after step 214 has been performed. Thus, a hard mask 227 has been formed. The length of the mask 227 in-plane corresponds to the physical (and magnetic) length of the free layer. Portions of the layers 224, 225 and 226 have been removed, leaving free layer 224′, second nonmagnetic spacer layer 225′ and second reference layer 226′.

A refill step is performed, via step 216. Step 216 provides an insulating refill around the free layer 224′. For example, step 216 may include blanket depositing an insulating layer over the region including the magnetic junction 220. For example, silicon nitride (e.g. Si₃N₄) or silicon oxide (e.g. SiO₂) may be deposited. A conformal deposition method such as PECVD. A portion of the insulating layer may be removed using an anisotropic etch, such as an RIE. FIG. 14 depicts the magnetic junction 220 after such an RIE has been performed. Thus, an insulator 228 has been provided. Because the removal has been carried out, the mask 227 is exposed.

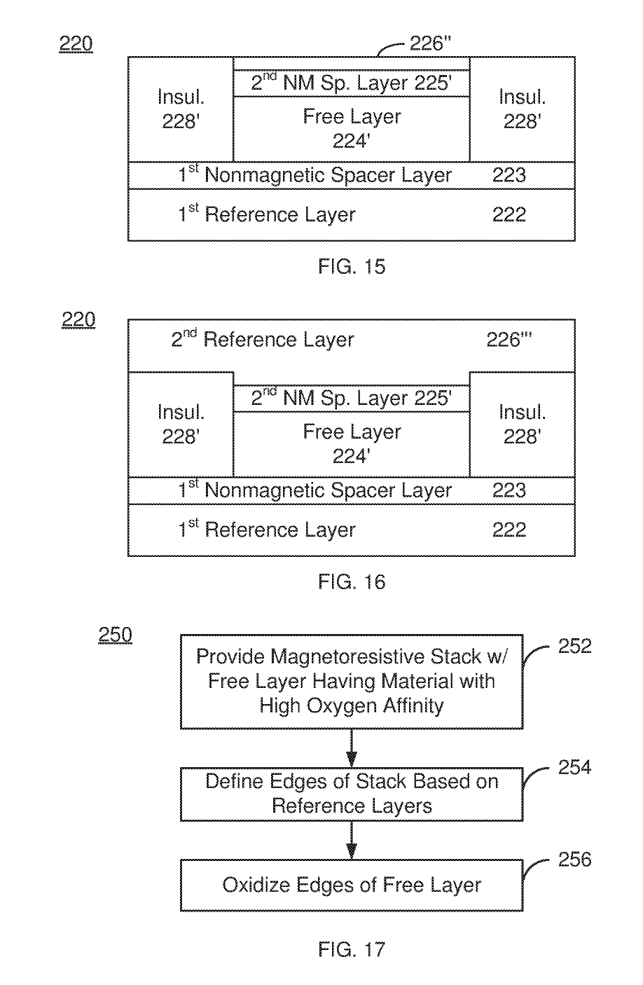

A remaining portion of the layer 226′ is exposed, via step 218. Step 218 may include removing the remainder of the hard mask 227 using an RIE. The RIE may remove part of the insulating layer 228 and part of the reference layer 226′. FIG. 15 depicts the magnetic junction 220 after step 218 has been performed. Thus, a remaining portion of the reference layer 226″ is exposed. A portion of the insulating layer 228′ also remains.

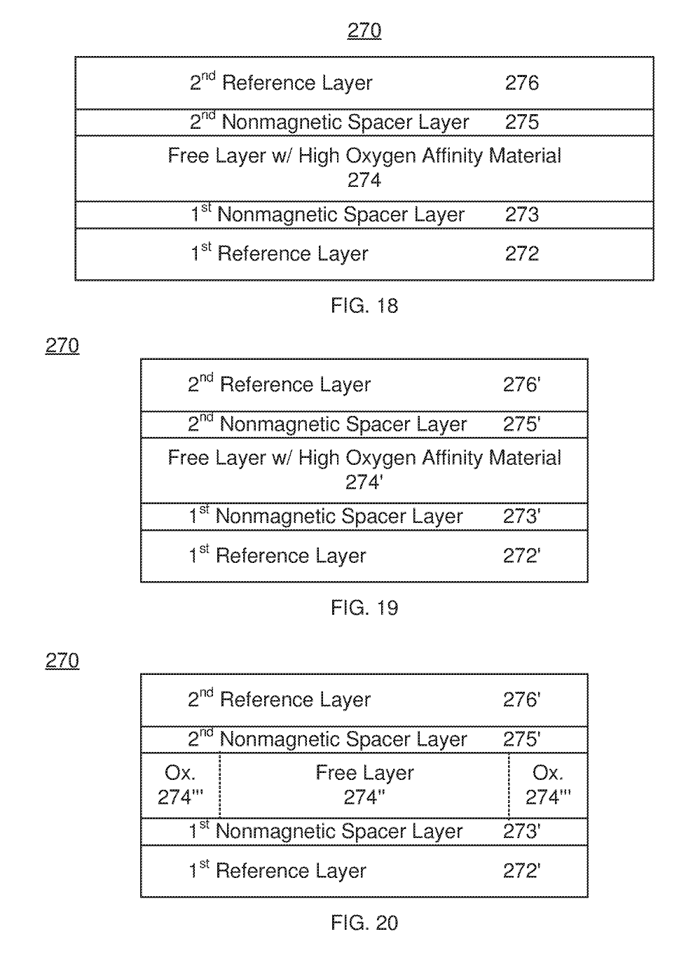

Another fixed magnetic layer is provided, via step 219. Step 219 may include depositing a multilayer. The magnetic layer deposited in step 219 and the remaining portion of the layer 226″ form the second reference layer. FIG. 18 depicts the magnetic junction 220 after step 219 is performed. Thus, the second reference layer 226′″ has been formed. Steps 214 through 219 may be viewed as forming the free layer with a magnetic length less than the magnetic length of the reference layers because the second reference layer 226′″ having a magnetic length longer than that of the free layer 224′ is formed. Thus, a magnetic junction analogous to the magnetic junctions 100A, 100B, 100C, 100D, 100E and 100F may be formed.

Using the method 210, the magnetic junction(s) 220 may be formed. The free layer 224′ may be fabricated with a shorter magnetic length and a shorter physical length than the magnetic and physical lengths of the reference layers 222 and 226′″. As a result, a magnetic junction having free layer(s) with improved switching characteristics may be achieved.

FIG. 17 is a flow chart depicting an exemplary embodiment of a method 250 for providing a layer for magnetic junction usable in a magnetic device and including a free layer having a reduced magnetic length. For simplicity, some steps may be omitted, performed in another order, include substeps and/or combined. FIGS. 18-20 depict an exemplary embodiment of a magnetic junction 270 during fabrication using the method 250. For clarity, only the reference layers, free layer and nonmagnetic spacer layers are shown in FIGS. 18-20. However, other layers including but not limited to PEL(s), texture blocking coupling layer(s) and/or other layers may be included. The method 250 is thus described in the context of the magnetic junction 270. However the method 250 may be used in forming other magnetic junction(s). Further, multiple magnetic junctions may be simultaneously fabricated. Further, the method 250 may start after other steps in forming a magnetic memory have been performed.

A magnetoresistive stack for the magnetic junction 250 is provided, via step 252. Step 252 includes providing material(s) for a free layer that include not only magnetic material(s), but also one or more materials having a higher oxygen affinity than the magnetic material(s). For example, free layer materials such as CoFeB may be deposited along with Mg, Al, Ti, Ta, W, Zr and/or V in step 252. In some embodiments, step 252 includes depositing at least five atomic percent and not more than fifteen atomic percent of the high oxygen affinity materials.

FIG. 18 depicts the magnetic junction 270 after step 252 is performed. Thus, layers for the first reference layer 272, first nonmagnetic spacer layer 273, free layer including high oxygen affinity material(s) 274, second nonmagnetic spacer layer 275 and second reference layer 276 have been deposited. Providing each layer 272, 273, 274, 275 and 276 may include multiple substeps. For example, one or more multilayers may be deposited as part of providing the materials for the first reference layer 272. The materials for the layers 272, 273, 274, 275 and 276 are analogous to those described above for the magnetic junctions 100, 100G and 100H.

The edges of the magnetic junction 270 are physically defined, via step 254. Step 254 may include providing a hard mask covering the region corresponding to the desired magnetic length of the reference layers and removing the exposed portion of the layers 222, 223, 224, 225 and 226. This removal may include an ion mill or RIE. FIG. 19 depicts the magnetic junction 270 after step 254 has been performed. Thus, a mask (not shown) has been formed. Portions of the layers 272, 273, 274, 275 and 276 have been removed, leaving first reference layer 272′, first nonmagnetic spacer layer 273′, free layer 274′, second nonmagnetic spacer layer 275′ and second reference layer 276′. The size of the layers 272′, 273′, 274′, 275′ and 276′ may be the desired physical and magnetic length of the reference layer(s) 272′ and/or 276′.

A portion of the free layer 274′ is oxidized such that the free layer magnetic length is less than the free layer physical length, via step 256. For example, an oxygen plasma treatment may be used to oxidize the sides of the free layer 224. FIG. 20 depicts the magnetic junction 270 after step 256 is performed. Thus, the magnetic junction 270 has been exposed to the oxygen plasma. The free layer 274″ has been reduced in effective size due to the oxidation of regions 274′″. In some embodiments, the oxygen penetrates at least one nanometer and not more than five nanometers into the edges of the free layer 274′. Each of the oxidized portions 274′″ may be up to five nanometers wide. The reference layers 272′ and 276′ may, therefore, extend up to five nanometers further than the free layer 274″ on each side off the free layer 274″. The remaining, unoxidized portion 274″ functions as the free layer.

Using the method 250, the magnetic junction(s) 270 may be formed. The free layer 274′ may be fabricated with a shorter magnetic length than the magnetic and physical lengths of the reference layers 272′ and 276′. As a result, a magnetic junction having free layer(s) with improved switching characteristics may be achieved.

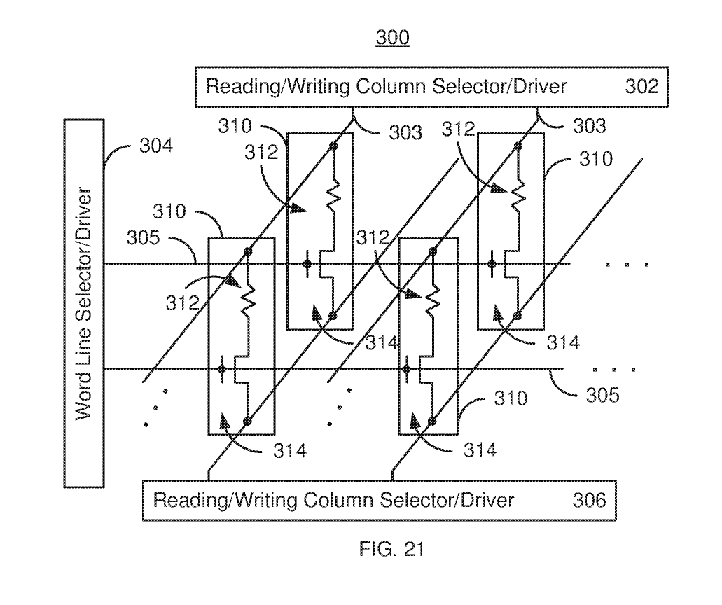

FIG. 21 depicts an exemplary embodiment of a memory 300 that may use one or more of the magnetic junctions 100, 100A, 100B, 100C, 100D, 100E, 100F, 100G, 100H and/or other magnetic junction including a shortened magnetic length free layer such as the free layer 140, 140A and/or 140G. The magnetic memory 300 includes reading/writing column select drivers 302 and 306 as well as word line select driver 304. Note that other and/or different components may be provided. The storage region of the memory 300 includes magnetic storage cells 310. Each magnetic storage cell includes at least one magnetic junction 312 and at least one selection device 314. In some embodiments, the selection device 314 is a transistor. The magnetic junctions 312 may be one of the 100, 100A, 100B, 100C, 100D, 100E, 100F, 100G, 100H and/or other magnetic junction including the diluted magnetic layer within the free layer. Although one magnetic junction 312 is shown per cell 310, in other embodiments, another number of magnetic junctions 312 may be provided per cell. As such, the magnetic memory 300 may enjoy the benefits described above.

A method and system for providing a magnetic junction and a memory fabricated using the magnetic junction has been described. The method and system have been described in accordance with the exemplary embodiments shown, and one of ordinary skill in the art will readily recognize that there could be variations to the embodiments, and any variations would be within the spirit and scope of the method and system. Accordingly, many modifications may be made by one of ordinary skill in the art without departing from the spirit and scope of the appended claims.

We claim:

1. A magnetic junction usable in a magnetic device comprising:
a first reference layer having a first reference layer magnetic length;
a first nonmagnetic spacer layer;
a free layer, the free layer being switchable between a plurality of stable magnetic states, the first nonmagnetic spacer layer being between the first reference layer and the free layer, the free layer having a free layer magnetic length and a free layer physical length, the free layer magnetic length being less than the first reference layer magnetic length, the free layer magnetic length being less than the free layer physical length, the free layer magnetic length having a first end and a second end opposite to the first end, the free layer and the first reference layer being oriented such that the first reference layer magnetic length extends past the first end and past the second end of the free layer;
a second nonmagnetic spacer layer, the free layer being between the first nonmagnetic spacer layer and the second nonmagnetic spacer layer; and
a second reference layer having a second reference layer magnetic length greater than the free layer magnetic length, the second nonmagnetic spacer layer being between the free layer and the second reference layer, the free layer and the second reference layer being oriented such that the second reference layer magnetic length extends past the first end and past the second end of the free layer.

2. The magnetic junction of claim 1 wherein the free layer has a free layer perpendicular magnetic anisotropy energy greater than a free layer out-of-plane demagnetization energy.

3. The magnetic junction of claim 1 wherein at least one of the first reference layer and the second reference layer is a synthetic antiferromagnet including a first magnetic layer, a second magnetic layer and a nonmagnetic coupling layer between the first magnetic layer and the second magnetic layer.

4. The magnetic junction of claim 1 wherein at least one of the first reference layer and the second reference layer is a shared reference layer.

5. The magnetic junction of claim 1 wherein the first reference layer magnetic length extends past the first end of the free layer magnetic length by at least five nanometers and extends past the second end of the free layer magnetic length by at least five nanometers and wherein the second reference layer magnetic length extends past the first end of the free layer magnetic length by at least five nanometers and extends past the second end of the free layer magnetic length by at least five nanometers.

6. The magnetic junction of claim 5 wherein the first reference layer magnetic length extends past the first end of the free layer magnetic length by not more than ten nanometers and extends past the second end of the free layer magnetic length by not more than ten nanometers and wherein the second reference layer magnetic length extends past the first end of the free layer magnetic length by not more than ten nanometers and extends past the second end of the free layer magnetic length by not more than ten nanometers.

7. The magnetic junction of claim 5 wherein the layer magnetic length is substantially centered with respect to at least one of the first reference layer magnetic length and the second reference layer magnetic length.

8. The magnetic junction of claim 1 wherein the free layer includes a magnetic material and at least one material having a greater oxygen affinity than the magnetic material.

9. The magnetic junction of claim 1 wherein the free layer physical length is substantially the same as a second reference layer physical length.

10. A magnetic memory comprising:
a plurality of magnetic storage cells, each of the plurality of magnetic storage cells including at least one magnetic junction having a first reference layer, a first nonmagnetic spacer layer, a free layer, a second nonmagnetic spacer layer and a second reference layer, the first reference layer having a first reference layer magnetic length, the free layer being switchable between a plurality of stable magnetic states, the first nonmagnetic spacer layer residing between the first reference layer and the free layer, the free layer having a free layer magnetic length and a free layer physical length, the free layer magnetic length being less than the first reference layer magnetic length, the free layer magnetic length being less than the free layer physical length, the free layer magnetic length having a first end and a second end opposite to the first end, the free layer and the first reference layer being oriented such that the first reference layer magnetic length extends past the first end and past the second end of the free layer, the free layer being between the first nonmagnetic spacer layer and the second nonmagnetic spacer layer, the second reference layer having a second pinned magnetic layer greater than the free layer magnetic length, the second nonmagnetic spacer layer being between the free layer and the second reference layer, the free layer and the second reference layer being oriented such that the second reference layer magnetic length extends past the first end and past the second end of the free layer; and
a plurality of bit lines coupled with the plurality of magnetic storage cells.

11. A method for providing magnetic junction usable in a magnetic device, the method comprising:
providing a magnetoresistive stack including at least a first fixed magnetic layer, a first nonmagnetic layer, a free magnetic layer, a second nonmagnetic layer and a second fixed magnetic layer, the first fixed magnetic layer corresponding to a first reference layer having a first reference layer magnetic length, the first nonmagnetic layer corresponding to a first nonmagnetic spacer layer, the free magnetic layer corresponding to a free layer switchable between a plurality of stable magnetic states using a write current passed through the magnetic junction, the second nonmagnetic layer corresponding to a second nonmagnetic spacer layer, the second fixed magnetic layer corresponding to at least a portion of a second reference layer, the first nonmagnetic spacer layer residing between the first reference layer and the free layer, the free layer being between the first nonmagnetic spacer layer and the second nonmagnetic spacer layer, the second nonmagnetic spacer layer being between the free layer and the second reference layer;
defining a free layer magnetic length for the free layer, the free layer magnetic length being less than a first reference layer magnetic length of the first reference layer and being less than a second reference layer magnetic length of the second reference layer, the free layer magnetic length being less than a free layer physical length, the free layer magnetic length having a first end and a second end opposite to the first end, the free layer and the first reference layer being oriented such that the first reference layer magnetic length extends past the first end and past the second end of the free layer, the free layer and the second reference layer being oriented such that the second reference layer magnetic length extends past the first end and past the second end of the free layer.

12. The method of claim 11 wherein at least one of the step of providing the magnetoresistive stack further includes:
providing a first magnetic layer for at least one of the first fixed magnetic layer and the second fixed magnetic layer;
providing a nonmagnetic coupling layer for the at least one of the first fixed magnetic layer and the second fixed magnetic layer; and
providing a second magnetic layer for the at least one of the first fixed magnetic layer and the second fixed magnetic layer, the nonmagnetic coupling layer being between the first magnetic layer and the second magnetic layer such the at least one of the first reference layer and the second reference layer is a synthetic antiferromagnet.

13. The method of claim 11 wherein at least one of the first reference layer and the second reference layer is a shared reference layer.

14. The method of claim 11 wherein the first reference layer magnetic length extends past the first end of the free layer magnetic length by at least five nanometers and extends past the second end of the free layer magnetic length by at least five nanometers and wherein the second reference layer magnetic length extends past the first end of the free layer magnetic length by at least five nanometers and extends past the second end of the free layer magnetic length by at least five nanometers.

15. The method of claim 14 wherein the first reference layer magnetic length extends past the first end of the free layer magnetic length by not more than ten nanometers and extends past the second end of the free layer magnetic length by not more than ten nanometers and wherein the second reference layer magnetic length extends past the first end of the free layer magnetic length by not more than ten nanometers and extends past the second end of the free layer magnetic length by not more than ten nanometers.

16. The method of claim 11 wherein the free magnetic layer includes a magnetic material and at least one material having a greater oxygen affinity than the magnetic material and step of defining the free layer magnetic length further includes:
removing a portion of the magnetoresistive stack including a portion of the second fixed magnetic layer, a portion of the second nonmagnetic layer and a portion of the free magnetic layer, forming the second reference layer and the second nonmagnetic spacer layer, the second reference layer having a second reference layer physical length, the free layer having a free layer physical length; and
oxidizing a portion of the free layer such that the free layer magnetic length is less than the free layer physical length.

17. The method of claim 16 wherein the free layer physical length is substantially the same as a second reference layer physical length.
